(19) United States
(12) Patent Application Publication
(10) Pub. No.: US 2009/0288872 A1
(43) Pub. Date: Nov. 26, 2009

(54) Printed circuit board including outmost fine circuit pattern and method of manufacturing the same

(75) Inventors: Han Kim, Gyunggi-do (KR); Mi Sun Hwang, Gyunggi-do (KR); Suk Won Lee, Gyunggi-do (KR); Chang Gun Oh, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/219,078

(22) Filed: Jul. 15, 2008

(30) Foreign Application Priority Data
May 26, 2008 (KR) 10-2008-0048705

(51) Int. Cl. H05K 1/02; H05K 3/36

(52) U.S. Cl. 174/262; 29/830

(57) ABSTRACT

Disclosed herein is a printed circuit board including an outmost fine circuit pattern. In the board, an end of a via, which has the minimum diameter, is connected to the outmost circuit layer of a substrate. The end surface, having the minimum diameter, is positioned at the outmost layer, so that the outmost circuit layer of the substrate, which needs to have a relatively high density in order to mount chips, compared to other circuit layers, can be more finely formed.

### CROSS REFERENCE TO RELATED APPLICATION

This application claims the benefit of Korean Patent Application No. 10-2008-0048705, filed May 26, 2008, entitled “PRINTED CIRCUIT BOARD INCLUDING OUTMOST FINE CIRCUIT PATTERN AND METHOD OF MANUFACTURING THE SAME”, which is hereby incorporated by reference in its entirety into this application.

### BACKGROUND OF THE INVENTION

1. Field of the Invention

The present invention relates generally to a printed circuit board including an outmost fine circuit pattern and a method of manufacturing the printed circuit board, and, more particularly, to a printed circuit board in which a via, an end of which has the minimum diameter, is connected to the outmost circuit layer of a substrate, and a method of manufacturing the printed circuit board.

2. Description of the Related Art

These days, in response to the miniaturization, the high-integration, and the multifunctionalization of electronic products, BGA package substrates are being rapidly developed in order to realize a fine circuit pattern having a lighter and smaller structure and a high density. Further, in mobile telephones, to which CSP (Chip-Sized Package) products are predominantly applied, in order to meet the demands of multifunctionalization, in which new optional functions are added to existing functions, the number of signal lines of a semiconductor device is rapidly being increased.

Particularly, fine circuit patterns, having a lighter and smaller structure, are mainly required for the manufacture of CSP products in which semiconductor devices are mounted on a BGA package substrate.

FIGS. 1A to 1G are cross-sectional views showing a process of manufacturing a conventional BGA package substrate.

As shown in FIG. 1A, a copper clad laminate 11, in which copper film layers 13 and 13′ are formed on both surfaces of an insulating resin layer 12, is prepared, and then an internal circuit pattern is formed on the copper film layers 13 and 13′ of the copper clad laminate 11. Subsequently, prepregs 14 and 14′ and copper films 15 and 15′ are sequentially formed on both surfaces of the copper clad laminate 11, including the internal circuit pattern formed thereon.

Thereafter, as shown in FIG. 1B, with the purpose of assuring the connection between the copper film layers 13 and 13′ and the copper films 15 and 15′, blind via-holes a are formed in the resulting substrate using laser machining, and a through-hole b is formed to completely pass through the substrate from the upper copper film 15 to the lower copper film 15′ by drilling.

As shown in FIG. 1C, to achieve an electrical connection between the blind via-holes a and the through-hole b, copper plating layers 16 and 16′ are formed on the upper and lower copper films 15 and 15′, the inner walls of the blind via-holes a and the inner wall of the through-hole b.

As shown in FIG. 1D, an external circuit pattern is formed on the upper and lower copper films 15 and 15′ and the upper and lower copper layers 16 and 16′ using a photolithography process.

As shown in FIG. 1E, solder resists 17 and 17′ are applied to the upper and lower surfaces of the substrate on which the external circuit pattern is formed, and are then preliminarily dried.

As shown in FIG. 1F, upper openings c, which correspond to respective wire bonding pads, are formed in the upper solder resist 17, and lower openings d, which correspond to respective solder ball pads, are formed in the lower solder resist 17′.

Finally, as shown in FIG. 1G, upper gold plating layers 18, functioning as the wire boding pads, are formed in the upper openings c of the upper solder resist 17, and lower gold plating layers 18′, functioning as the wire bonding pads, are formed in the lower openings d of the lower solder resist 17′, with the result that a conventional BGA package substrate is manufactured.

In the conventional BGA package substrate, which is constructed in the above-described manner, the external circuit patterns 15 and 15′ are connected to ends of the via-holes, each of which has the greatest diameter along the length of the via-hole, and the bonding pads 18 and 18′ are provided around the via-holes. In the conventional configuration, however, the increase in the area of the via-holes, to which the external circuit patterns are connected, and the peripheral disposition of the external circuit patterns due to the depression of the via-holes have an adverse effect on the ability to realize external fine circuit patterns at high density.

### SUMMARY OF THE INVENTION

Accordingly, the present invention has been made keeping in mind the above problems occurring in the prior art, and the present invention provides a printed circuit board which is configured such that the outmost circuit pattern of a substrate is connected to an end of a via, which has the greatest diameter along the length of the via, thus enabling the formation of a fine circuit on the outmost circuit layer.

Further, the present invention provides a printed circuit board including a landless via and a method of manufacturing the printed circuit board, in which an upper land, which is connected to the end of the via having the minimum diameter, is removed, so that a fine circuit may be formed on the outmost layer and the connectivity between the via and the circuit pattern is improved.

In one aspect, the present invention provides a printed circuit board including an outmost fine circuit pattern layer, including: a first insulating layer; a first circuit layer including a first circuit pattern, formed on a surface of the first insulating layer; a second circuit layer including a first lower land, formed on the other surface of the first insulating layer; a first via for electrical connection between the first circuit pattern and the first lower land; a second insulating layer; a third circuit layer including a second circuit pattern, formed on a surface of the second insulating layer; a fourth circuit layer including a second lower land, formed on the other surface of the second insulating layer; a second via for electrical connection between the second circuit pattern and the second lower land; a third insulating layer disposed between the second circuit layer and the fourth circuit layer; and a conductive bump for electrical connection between the first lower land and the second lower land; wherein the first via is configured such that a diameter of the first via is reduced at a constant rate toward the first circuit pattern from the first lower land, while the second via is configured such that a diameter of the second via is reduced at a constant rate toward the second circuit pattern from the second lower land.

The first circuit pattern contacting the first via may have a line width smaller than a minimum diameter of the first via, and the second circuit pattern contacting the second via may have a line width smaller than a minimum diameter of the second via.

The first circuit pattern may be extended across an end surface of the first via while being in contact with the end surface of the first via, and the second circuit pattern may be extended across an end surface of the second via while being in contact with the end surface of the first via.

The bump may be made of conductive paste.

In another aspect, the present invention provides a method of manufacturing a printed circuit board including an outmost fine circuit pattern layer, the method including: preparing a first double-sided substrate including a first insulating layer, a first lower copper layer formed on a surface of the first insulating layer, a second circuit layer including a first lower land, formed on the other surface of the first insulating layer, and a first via which is reduced in diameter at a constant rate toward the first lower copper layer from the first lower land for interlayer connection; preparing a second double-sided substrate including a second insulating layer, a third lower copper layer formed on a surface of the second insulating layer, a fourth circuit layer including a second lower land, formed on the other surface of the second insulating layer, and a second via which is reduced in diameter at a constant rate toward the third lower copper layer from the second lower land for interlayer connection; disposing a third insulating layer between the second circuit layer and the fourth circuit layer such that the first lower land and the second lower land are electrically connected to each other though a conductive bump; and forming a first circuit layer including a first circuit pattern connected to the first via on the first lower copper layer and forming a third circuit layer including a third circuit pattern connected to the second via on the third lower copper layer.

The first circuit pattern, contacting the first via, may have a line width smaller than a minimum diameter of the first via, and the second circuit pattern, contacting the second via, may have a line width smaller than a minimum diameter of the second via.

In the method, the preparing the first double-sided substrate may include: preparing a first substrate, which includes a first insulating layer, a first copper layer formed on a surface of the first insulating layer and having a first upper copper layer and a first lower copper layer, and a second copper layer formed on the other surface of the first insulating layer; forming a first via-hole through the second copper layer and the first insulating layer; forming a plating layer on an inner wall of the first via-hole; forming a second circuit layer including the first via and the first lower land on the first via-hole and the second copper layer; and removing the first upper copper layer.

In the method, the preparing the second double-sided substrate may include: preparing a second substrate, which includes a second insulating layer, a third copper layer formed on a surface of the second insulating layer and having a third upper copper layer and a third lower copper layer, and a fourth copper layer formed on the other surface of the second insulating layer; forming a second via-hole through the fourth copper layer and the second insulating layer; forming a plating layer on an inner wall of the second via-hole; forming a fourth circuit layer including the second via and the second lower land on the second via-hole and the fourth copper layer; and removing the third upper copper layer.

In the method, the disposingthe third insulating layer may include: forming the conductive bump on the second lower land; disposing the third insulating layer on the fourth circuit layer; and placing the first double-sided substrate on the second double-sided substrate such that the conductive bump comes into contact with the first lower land.

In the method, the forming the first and third circuit layers may include: placing resist layers on the first lower copper layer and the third lower copper layer, respectively; forming a first opening, adapted to form the first circuit layer including the first circuit pattern, and a second opening, adapted to form the third circuit layer including the third circuit pattern, in the respective resist layers; and plating the first and second openings and removing the remaining resist layers.

In the method, the upper and lower copper layers may be attached to each other using a releasing agent.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A to 1G are cross-sectional views showing a process of manufacturing a conventional printed circuit board;

FIG. 2 is a cross-sectional view showing a printed circuit board including an outmost fine circuit pattern, according to an embodiment of the present invention; and

FIGS. 3 to 17 are cross-sectional views showing a process of manufacturing the printed circuit board including an outmost fine circuit pattern, according to the embodiment of the present invention.

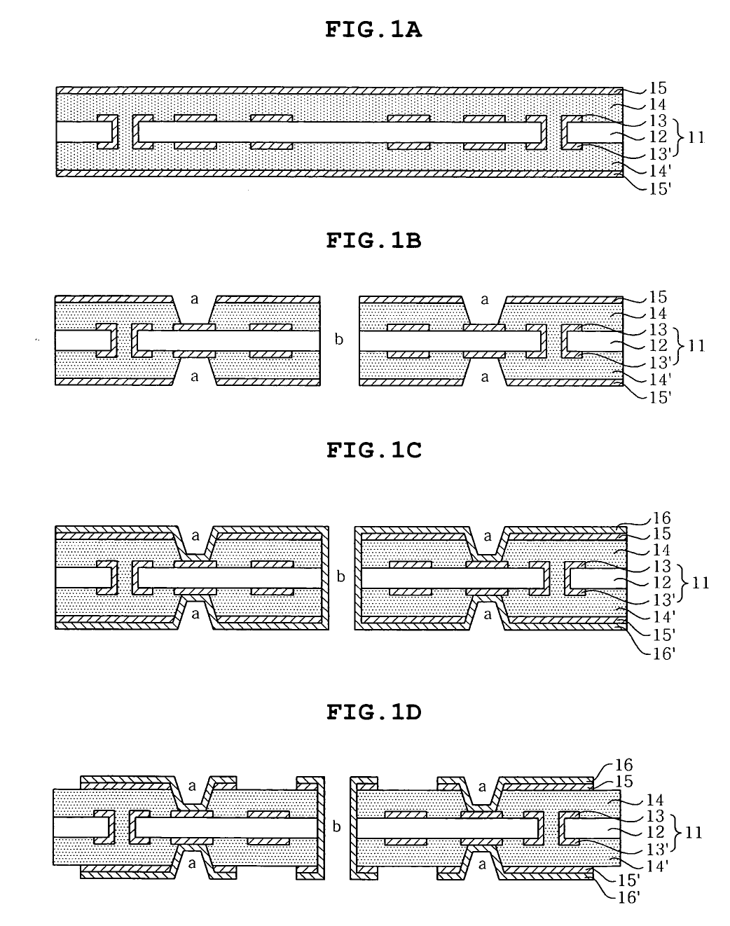

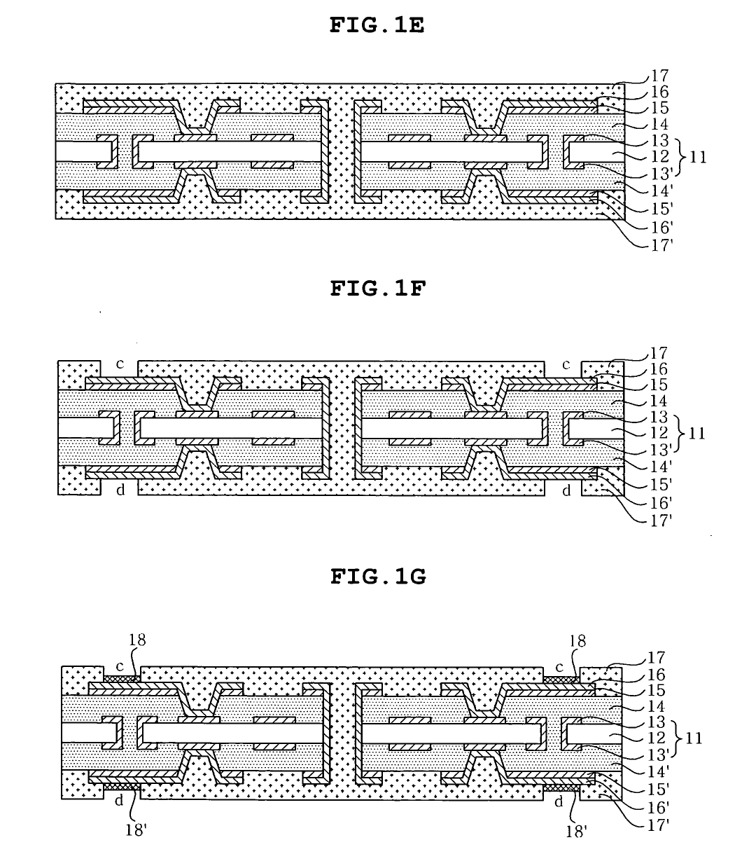

### DESCRIPTION OF THE PREFERRED EMBODIMENTS

Hereinafter, a printed circuit board including an outmost fine circuit pattern according to the present invention will be described in greater detail with reference to the accompanying drawings. Throughout the accompanying drawings, the same reference numerals are used to designate the same or similar components, and redundant descriptions thereof are omitted. In the following description, the terms “first”, “second” and the like are used to differentiate a certain component from other components, but the configuration of such components should not be construed to be limited by the terms.

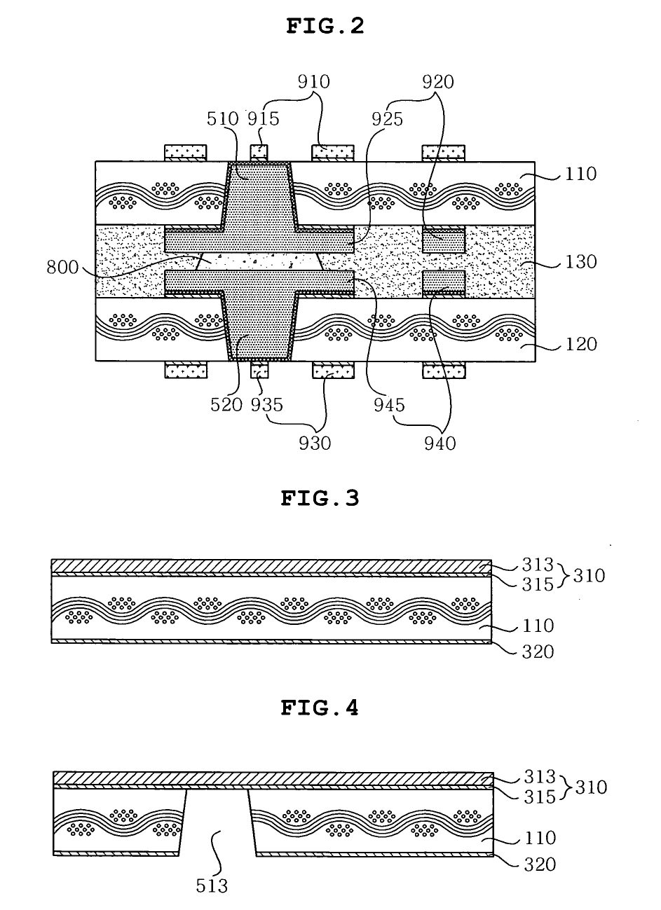

FIG. 2 is a cross-sectional view of a printed circuit board including a via having no upper land, according to an embodiment of the present invention. As shown in FIG. 2, the present invention is configured such that the end of a via that has the minimum diameter is connected to the outmost circuit layer of a printed circuit board.

More specifically, the printed circuit board according to this embodiment of the present invention comprises a first circuit layer 910 including a first circuit pattern 915 formed on a surface of a first insulating layer 110, a second circuit layer 920 including a first lower land 925 formed on the other surface of the insulating layer 110, a first via 510 for electrical connection between the first circuit pattern 915 and the first lower land 925, a third circuit layer 930 including a second circuit pattern 935 formed on a surface of the second insulating layer 120, a fourth circuit layer 940 including a second lower land 945 formed on the other surface of the second insulating layer 120, a second via 520 for electrical connection between the second circuit pattern 935 and the second lower land 945, a third insulating layer 130 disposed between the second circuit layer 920 and the fourth circuit layer 940, and a conductive bump 800 for electrical connection between the first lower land 925 and the second lower land 930.

The first circuit layer 910 and the third circuit layer 930, which are exposed surfaces of the substrate, constitute the outmost layers of the printed circuit board according to the present invention.

The first via 510 has a configuration such that it is reduced in diameter at a constant rate toward the first circuit pattern 915 from the first lower land 925, while the second via 520 has a configuration such that it is reduced at a constant rate in diameter toward the second circuit pattern 935 from the second lower land 945. The first via 510 and the second via 520 may have frusto-conical shapes. A laser drill such as a CO₂ or YAG laser, which is typically used for the formation of a via-hole 513 (see FIG. 4), may be used to form a via-hole 513 having a frusto-conical shape.

The first via 510, which is formed in the printed circuit board according to the present invention, is configured such that the end of the first via 510 that has the minimum diameter is connected to the first circuit pattern 915 formed on the first circuit layer 910, which is the upper outmost layer, while the second via-hole 520 is also configured such that an end of the via-hole 520 is connected to the third circuit pattern 935 formed on the third circuit layer 903, which is the lower outmost layer. In this case, the first via 510 and the second via 520 may be comprised of, for example, copper.

The conductive bump 800, which functions to provide an electrical connection between the first lower land 925 and the second lower land 945, may comprise conductive paste. In this embodiment, although only the conductive bump, which is provided for the connection between the first lower land 925 and the second lower land 945, has been shown and described, it is to be noted that other conductive bumps, which assure the connection between the circuit pattern of the second circuit layer 920 and the circuit pattern of the fourth circuit layer 940, rather than between the lower lands of the vias, may be optionally provided.

The first to third insulating layers 110, 120 and 130 are interposed between the first to fourth circuit layers 910, 920, 930 and 940 to isolate the layers from each other, and may be comprised of insulating resin such as epoxy resin.

The printed circuit board according to this embodiment of the present invention is advantageous in that the end of the via having the minimum diameter is positioned to face the outmost layer, so that the outmost circuit layer of the substrate, which needs to have a relatively high density in order to mount chips thereon, compared to other circuit layers, may be more finely formed.

Further, the printed circuit board according to the present invention may comprise the first circuit pattern 915 and the second circuit pattern 935, each of which has a line width smaller than the minimum diameter of the first and second vias 510 and 520. In other words, a landless via, which does not have an upper land on the outmost layer of the printed circuit board, is realized, and thus the outmost circuit layer of the substrate can be more finely formed, which is advantageous.

The process of manufacturing the printed circuit board including a via having no upper land, according to an embodiment of the present invention, will now be described. FIGS. 3 to 17 are flow process views sequentially showing the process of manufacturing the printed circuit board including a via having no upper land.

As shown in FIG. 3, a first insulating layer 110, which includes a first copper layer 310 on the upper surface thereof and a second copper layer 320 on the lower surface thereof, is first prepared. The first copper layer 310 is comprised of two layers, i.e., a first lower copper layer 315 and a first upper copper layer 313 formed on the first lower copper layer 315. In this embodiment, first the lower copper layer 315 may have a thickness of about 3 μm, the first upper copper layer 313 may have a thickness of about 18 μm, and the second copper layer 320 may have a thickness of about 3 μm.

Thereafter, as shown in FIG. 4, a via-hole 513, which passes through the second copper layer 320 and the first insulating layer 110, is formed. In this embodiment, the via-hole 513 is formed, starting from the second copper layer 320, using a laser drill employing a CO₂ or YAG laser. Prior to machining using the laser drill, a window-formation operation of removing the portion of the second copper layer 320 corresponding to the first via-hole 513 may be conducted. When the via-hole 513 is formed using a laser drill, as in the embodiment shown in the drawing, on account of the intrinsic properties of the laser, the via-hole 513 tends to decrease in diameter at a constant rate in a direction away from the laser-irradiated surface, i.e., in a direction toward the first copper layer 310 from the second copper layer 320.

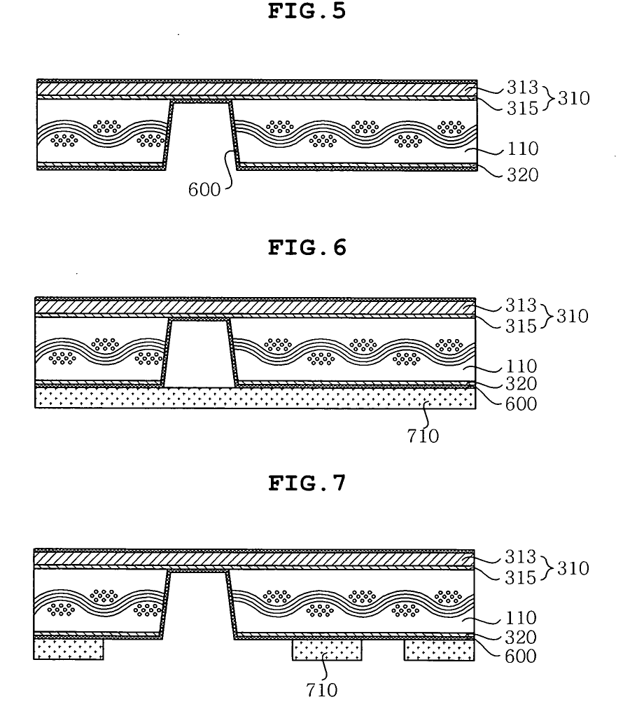

Subsequently, as shown in FIG. 5, an electroless plating operation is conducted to form an electroless plating layer 600 on the second copper layer 320 and the inner surface of the first via-hole 513. At this point, the electroless plating operation is a pretreatment operation for providing a conductive film required to form the first via 510 using electroless copper plating. In this operation, the electroless plating layer may be also provided on the first copper layer 310.

As shown in FIG. 6, a first resist layer 710 is formed under the first insulating layer 110. In this embodiment, the first resist layer 710 may be comprised of a photosensitive resist film.

As shown in FIG. 7, the first resist layer 710 is patterned. More specifically, the first resist layer 710 is patterned in a manner such that the first resist layer 710 is subjected to light exposure and development processes so that the first resist layer 710 has openings for forming a second circuit layer 920 including a first lower land 925.

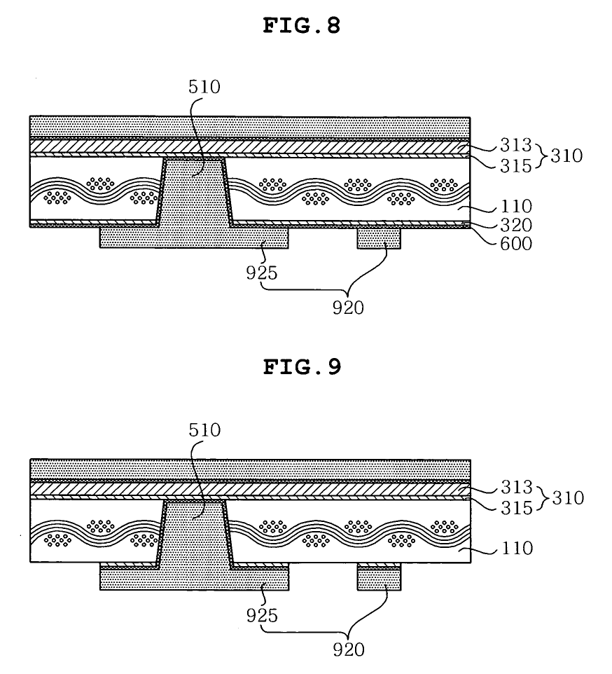

As shown in FIG. 8, the openings of the first resist layer 710 are subjected to electroplating, and then the remaining first resist layer 710 is removed. At this time, in this embodiment, a copper fill plating process is conducted to form a first via 510. Here, the electroplating may also be conducted on the first copper layer 310.

Subsequently, as shown in FIG. 9, flesh etching is conducted so as to form the second circuit layer 920, including the first lower land 925 connected to the first via 510, under the first insulating layer 110.

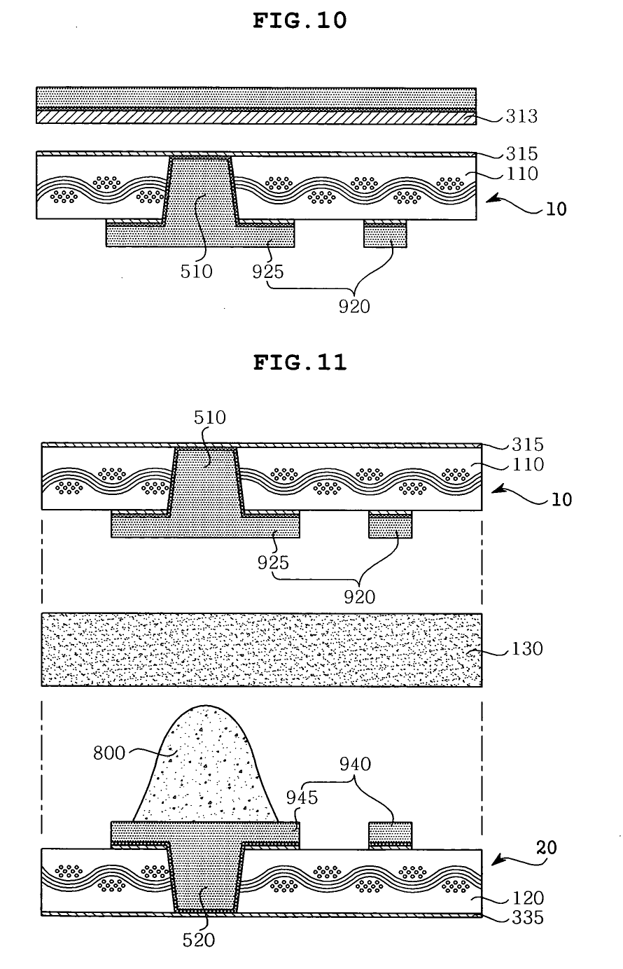

As shown in FIG. 10, the first upper copper layer 313 of the first copper layer 310 is removed. The first upper copper layer 313 and the first lower copper layer 315 may be easily separated from each other with the aid of a releasing agent (not shown) disposed therebetween. As alternatives to the releasing agent, other known materials, which are capable of separating the upper and lower copper layers from each other, may be used without limitation. Upon removing the first upper copper layer 313, the electroless plating and electroplating layers formed on the first upper copper layer 313 are also removed therewith.

As a result of the above-describe process, a first double-sided substrate 10 is manufactured, which comprises the first lower copper layer 315 formed on the surface of the first insulating layer 110, the second circuit layer 920, including the first lower land 925, formed on the other surface of the first insulating layer 110, and the first via 510 electrically connected to the first lower land 925.

Referring to FIG. 11, a second double-sided substrate 20 is further prepared through a process similar to the above-described process, which comprises a third lower copper layer 335 formed on the surface of a second insulating layer 120, a fourth circuit layer 940, including a second lower land 945, formed on the other surface of the first insulating layer 120, and a second via 520 electrically connected to the second lower land 945.

After the first double-sided substrate 10 and the second double-sided substrate 20 are prepared, the first and second double-sided substrates are positioned such that the end of each of the vias having the minimum diameter is located at the outmost layer of the substrate, and a third insulating layer 130 is disposed between the first and second double-sided substrates, as shown in the drawing. The third insulating layer 130, which is used in this embodiment, may be a semi-cured (B-stage) resin layer. B-stage refers to an intermediate stage in a curing reaction of resin, which is in a state capable of being deformed by a predetermined degree of heating and pressing.

Thereafter, a conductive bump 800 is formed on the second lower land 945. In this regard, the bump 800 is applied to the second lower land 945 in a screen printing manner. The screen print is conducted by transferring conductive paste to the second lower land 945 through a mask having openings, thus printing the conductive bump 800. More specifically, when the openings in the mask are correctly positioned, the conductive paste is applied on the upper surface of the mask. Thereafter, as the conductive paste is pressed using a squeegee, the conductive paste is extruded out through the openings in the mask and transferred to the second lower land 945. In this regard, the bump 800 may be printed to have a desired shape and height, and, although this is not shown in the drawing, the bump may be further formed on circuit patterns other than the second lower land for interlayer connection.

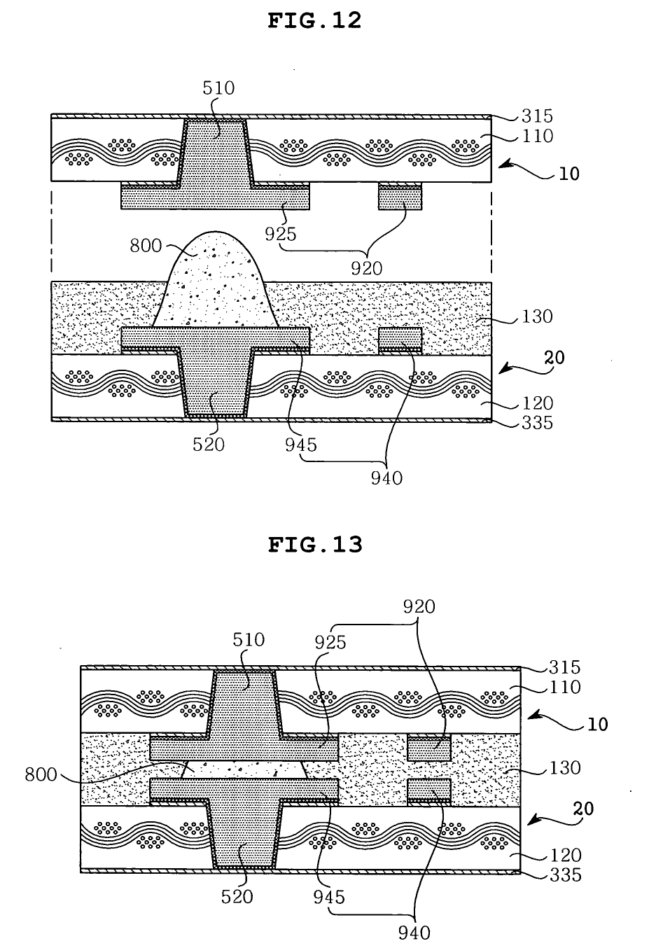

Subsequently, as shown in FIG. 12, the third insulating layer 130 is layered on the fourth circuit layer 940 such that the conductive bump 800 passes through the third insulating layer 130.

As shown in FIG. 13, the first double-sided substrate 10 and the second double-sided substrate 20 are pressed together and thus layered together using a press. At this point, the bump 800 is pressed between the first lower land 925 and the second lower land 945, with the result that the first lower land 925 and the second lower land 945 are electrically connected to each other.

Meanwhile, when the vias 510 and 520 are formed using the copper fill plating process as described above, the bottom surface of the via-hole may not be evenly plated, thus causing the generation of so-called dimples, because of the difference in height between a center region, corresponding to the via-hole, and a peripheral region around the center region. It is believed that the dimples incur defects of manufactured printed circuit boards, such as voids in the substrates, during the layering procedures, thus deteriorating process reliability. In this embodiment, thanks to the print and press processes of the conductive bump 800, dimples, which may occur in the first via 510 and the second via 520, are filled with the conductive paste constituting the bump 800, and are thus removed. Accordingly, it is possible to manufacture more reliable printed circuit boards.

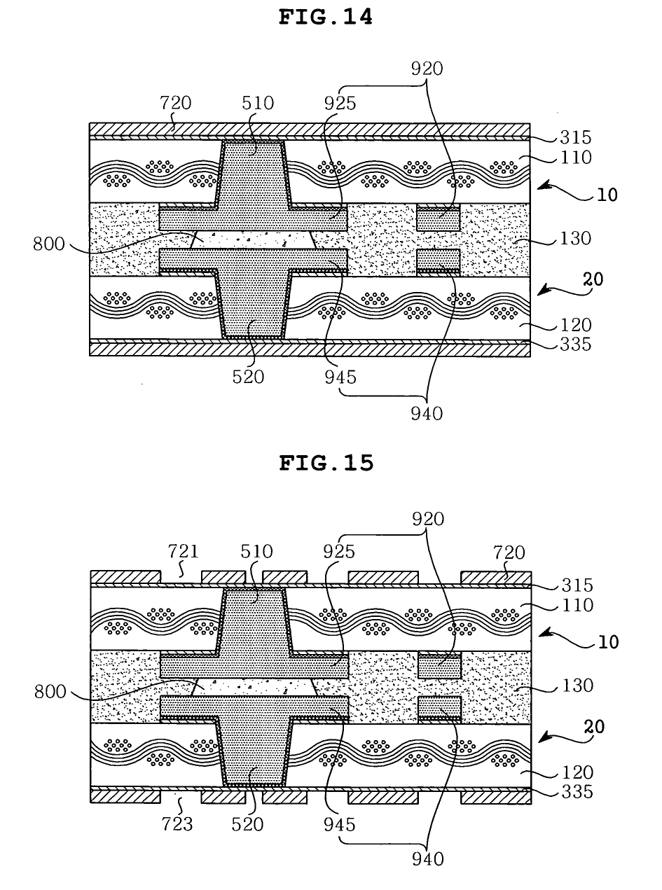

Thereafter, as shown in FIG. 14, second resist layers 720 are applied to the first lower copper layer 315 and the third lower copper layer 335.

Then, as shown in FIG. 15, the second resist layer 720 is subjected to light exposure and development processes, and thus is patterned, with the result that the second resist layer 720, formed on the first lower copper layer, is provided with openings 721 adapted to form a first circuit layer 910, including a first circuit pattern 915, while the second resist layer 720, formed on the third lower copper layer, is provided with openings 723 adapted to form a third circuit layer 930 including a second circuit pattern 935.

In this regard, in order to form line widths of first and second circuit patterns 915 and 935, which will be formed later, to be smaller than the minimum diameter of the first and second vias 510 and 520, the width of the opening 721 formed in the portion of the first lower copper layer corresponding to the first via 510, which is adapted to form the first circuit pattern 915, is set to be smaller than the minimum diameter of the first via 510. Similarly, the width of the opening 723 formed in the portion of the third lower copper layer corresponding to the second via 520, which is adapted to form the second circuit pattern 935, is set to be smaller than the minimum diameter of the second via 520. Here, it will be appreciated that the widths of the openings, which are adapted to form the first and second circuit patterns 915 and 935, may be set to be larger than the minimum diameters of the first and second vias 510 and 520, if required.

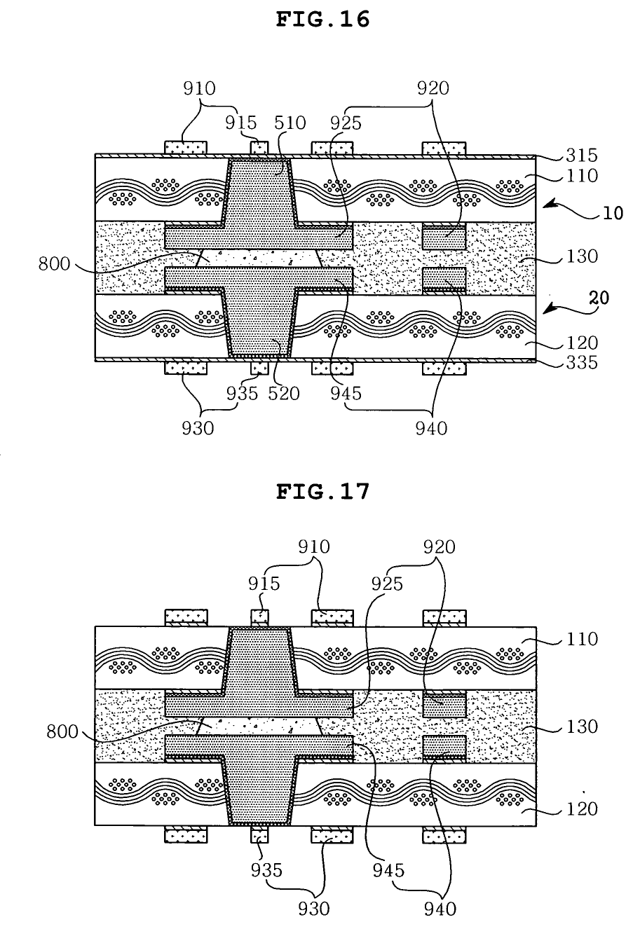

Subsequently, as shown in FIG. 16, the opening of the second resist layer 720 is subjected to electroplating, and then the remaining second resist layer 720 is removed.

As shown in FIG. 17, flesh etching is conducted so as to finish the first circuit layer 910 and the third circuit layer 930. Through the above-described process, the printed circuit board according to the embodiment of the present invention is manufactured, in which ends of vias have the minimum diameter along the length thereof and are located at the outmost circuit layers of the substrates.

As described above, the printed circuit board including an outmost fine circuit pattern according to the present invention has an advantage in that an end surface of a via having the minimum diameter is positioned at the outmost layer, so that the outmost circuit layer of the substrate, which needs to have a relatively high density in order to mount chips thereon, compared to other circuit layers, can be more finely formed.

Further, the printed circuit board according to the present invention has another advantage in that vias, which are positioned one over other, are connected to each other using a conductive bump disposed therebetween, thus eliminating dimples, which may occur therebetween.

In addition, the printed circuit board according to the present invention has a further advantage in that there is no upper land on the end surface of the via having the minimum diameter, thus enabling the outmost circuit layer of a substrate to be more finely formed.

In addition, the printed circuit board according to the present invention has still another advantage in that it is possible to easily manufacture the printed circuit board including a via having no upper land using upper and lower copper layers, which are attached to each other using a releasing agent disposed therebetween.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, the modifications, additions and substitutions should be also construed to fall within the scope of the present invention.

What is claimed is:

1. A printed circuit board including an outmost fine circuit pattern layer, comprising:
a first insulating layer;
a first circuit layer including a first circuit pattern, formed on a surface of the first insulating layer;
a second circuit layer including a first lower land, formed on the other surface of the first insulating layer;
a first via for electrical connection between the first circuit pattern and the first lower land;
a second insulating layer;
a third circuit layer including a second circuit pattern, formed on a surface of the second insulating layer;
a fourth circuit layer including a second lower land, formed on the other surface of the second insulating layer;
a second via for electrical connection between the second circuit pattern and the second lower land;
a third insulating layer disposed between the second circuit layer and the fourth circuit layer; and
a conductive bump for electrical connection between the first lower land and the second lower land;
wherein the first via is configured such that a diameter of the first via is reduced toward the first circuit pattern from the first lower land, while the second via is configured such that a diameter of the second via is reduced toward the second circuit pattern from the second lower land.

2. The printed circuit board according to claim 1, wherein the first circuit pattern, contacting the first via, has a line width smaller than a minimum diameter of the first via, and the second circuit pattern, contacting the second via, has a line width smaller than a minimum diameter of the second via.

3. The printed circuit board according to claim 1, wherein the first circuit pattern is extended across an end surface of the first via while being in surface contact with the end surface of the first via, and the second circuit pattern is extended across an end surface of the second via while being in surface contact with the end surface of the first via.

4. The printed circuit board according to claim 1, wherein the bump is made of conductive paste.

5. A method of manufacturing a printed circuit board including an outmost fine circuit pattern layer, the method comprising:
preparing a first double-sided substrate including a first insulating layer, a first lower copper layer formed on a surface of the first insulating layer, a second circuit layer including a first lower land, formed on the other surface of the first insulating layer, and a first via which is reduced in diameter toward the first lower copper layer from the first lower land for interlayer connection;
preparing a second double-sided substrate including a second insulating layer, a third lower copper layer formed on a surface of the second insulating layer, a fourth circuit layer including a second lower land, formed on the other surface of the second insulating layer, and a second via which is reduced in diameter toward the third lower copper layer from the second lower land for interlayer connection;
disposing a third insulating layer between the second circuit layer and the fourth circuit layer such that the first lower land and the second lower land are electrically connected to each other though a conductive bump; and
forming a first circuit layer including a first circuit pattern connected to the first via on the first lower copper layer and forming a third circuit layer including a third circuit pattern connected to the second via on the third lower copper layer.

6. The method according to claim 5, wherein the first circuit pattern, contacting the first via, has a line width smaller than a minimum diameter of the first via, and the second circuit pattern, contacting the second via, has a line width smaller than a minimum diameter of the second via.

7. The method according to claim 5., wherein the preparing the first double-sided substrate comprises:
preparing a first substrate, which includes a first insulating layer, a first copper layer formed on a surface of the first insulating layer and having a first upper copper layer and a first lower copper layer, and a second copper layer formed on the other surface of the first insulating layer;
forming a first via-hole through the second copper layer and the first insulating layer;
forming a plating layer on an inner wall of the first via-hole;
forming a second circuit layer including the first via and the first lower land on the first via-hole and the second copper layer; and
removing the first upper copper layer.

8. The method according to claim 5, wherein the preparing the second double-sided substrate comprises:
preparing a second substrate, which includes a second insulating layer, a third copper layer formed on a surface of the second insulating layer and having a third upper copper layer and a third lower copper layer, and a fourth copper layer formed on the other surface of the second insulating layer;
forming a second via-hole through the fourth copper layer and the second insulating layer;
forming a plating layer on an inner wall of the second via-hole;
forming a fourth circuit layer including the second via and the second lower land on the second via-hole and the fourth copper layer; and
removing the third upper copper layer.

9. The method according to claim 5, wherein the disposing the third insulating layer comprises:
forming the conductive bump on the second lower land;
disposing the third insulating layer on the fourth circuit layer; and
placing the first double-sided substrate on the second double-sided substrate such that the conductive bump comes into contact with the first lower land.

10. The method according to claim 5, wherein the forming the first and third circuit layers comprises:
placing resist layers on the first lower copper layer and the third lower copper layer, respectively;
forming a first opening, adapted to form the first circuit layer including the first circuit pattern, and a second opening, adapted to form the third circuit layer including the third circuit pattern, in the respective resist layers; and
plating the first and second openings and removing the remaining resist layers.

11. The method according to claim 7, wherein the upper and lower copper layers are attached to each other using a releasing agent.

12. The method according to claim 8, wherein the upper and lower copper layers are attached to each other using a releasing agent.
